(19) United States
(12) Patent Application Publication
(10) Pub. No.: US 2026/0290477 A1
(43) Pub. Date: Sep. 24, 2026

(54) DUAL STEP MULTI-LEVEL CELL PROGRAM METHOD FOR NON-VOLATILE MEMORY

(71) Applicant: Silicon Storage Technology, Inc., San Jose, CA (US)

(72) Inventors: Stefano Surico, Bussero (Milan) (IT); SIMONE BARTOLI, Mandello del Lario (IT); STEFANO SIVERO, Comun Nuovo (IT); GIUSEPPE MOIOLI, Alzano Lombardo (BG) (IT); XIAN LIU, Sunnyvale, CA (US); THAI LE, Ho Chi Minh (VN); AN VO, Ho Chi Minh (VN); JEAN FRANCOIS THIERY, Caromb (FR); SERGUEI JOURBA, Aix En Provence PACA (FR); CATHERINE DECOBERT, Pourrieres (FR); NHAN DO, Saratoga, CA (US); LORENZO BEDARIDA, Vimercate (IT)

(21) Appl. No.: 19/261,883

(22) Filed: Jul. 7, 2025

Related U.S. Application Data
(60) Provisional application No. 63/774,034, filed on Mar. 18, 2025.

(51) Int. Cl. G11C 16/34; G11C 16/10; G11C 16/26

(52) U.S. Cl. CPC G11C 16/3431; G11C 16/102; G11C 16/26

(57) ABSTRACT

A method and system that stores (n−1) partitions of a first image of code in a first set of banks in single-level cell format, wherein the first set of banks comprise (n−1) of n banks of flash memory cells, and stores (n−1) partitions of the first image as first significant bits and (n−1) partitions of a second image of code as second significant bits in a second set of banks in dual step multi-level cell format. The second set of banks comprise (n−1) of the n banks and the second set of banks comprises a bank not contained in the first set of banks. The first significant bits are either least significant bits or most significant bits of the flash memory cells, and the second significant bits are the other of the least significant bits and the most significant bits of the flash memory cells.

### RELATED APPLICATIONS

This application claims the benefit of U.S. Provisional Application No. 63/774,034, filed Mar. 18, 2025, and which is incorporated herein by reference.

### FIELD OF THE INVENTION

Numerous examples are disclosed of algorithms (i.e., methods) for updating software in flash memory in a system while the system is operating.

### BACKGROUND OF THE INVENTION

Complex software-based systems, such as automotive systems, utilize a substantial amount of software code stored in non-volatile storage. An example of such a system is shown in FIG. 1. System 100 comprises processing unit 101, memory 102, non-volatile storage 103, and network interface 104. Processing unit 101 comprises circuitry that can includes one or more microprocessors each comprising one or more processing cores. Memory 102 comprises DRAM, SRAM, or another type of volatile memory. Non-volatile storage 303 comprises an embedded NOR flash memory, a stand-alone NOR or NAND flash memory, a solid state drive, or another type of storage. A solid state drive can comprise one or more arrays of flash memory cells arranged in rows and columns. Network interface 104 comprises one or more of a wired transceiver (such as a network interface compliant with a wired protocol such as that known by the trademark ETHERNET) and a wireless transceiver (such as an interface compliant with a wireless protocol such as those known by the trademarks BLUETOOTH, RFID, NFC, WIFI, 3G, 4G, 5G, and LTE).

Non-volatile storage 103 stores code 105, which is software code that can be loaded into memory 102 and executed by processing unit 101. Code 105 can be updated over network interface 104, such as through an “over-the-air” (OTA) update in the situation where network interface 104 comprises a wireless transceiver that receives software code that is intended to update code already stored in the non-volatile storage 103. Code 105 might be updated while system 100 is in operation and code 105 is being executed by processing unit 101. In the situation where system 100 is an automotive vehicle, code 105 might be updated while the vehicle is in motion.

The ability to update code 105 while code 105 is being executed often is premised on creating multiple images of code 105, such as a primary image of code 105 and a secondary or backup image of code 105. This can be referred to as dual-image storage. When a first image of code 105 is being updated, code execution can be conducted from the second image of code 105. Similarly, when the second image of code 105 is being updated, code execution can be conducted from the first image of code 105. After the update is completed, one of the images can be discarded or written over.

FIGS. 2-5 depicts examples of flash memory cells that can be used in non-volatile storage 103. U.S. Pat. No. 5,029,130 (“the '130 patent”), which is incorporated herein by reference, discloses an array of split gate non-volatile memory cells, which are a type of flash memory cells. Such a memory cell 210 is shown in FIG. 2. Each memory cell 210 includes source region 14 and drain region 16 formed in semiconductor substrate 12, with channel region 18 of the semiconductor substrate 12 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 210 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 210 is programmed by source side injection (SSI) with hot electrons (where electrons are placed on the floating gate 20) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 210 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 210 for performing read, erase, and program operations:

TABLE NO 1
Operation of Flash Memory Cell 210 of FIG. 2

| | | |
|---|---|---|
| WL | BL | SL |

| | | | | | | |
|---|---|---|---|---|---|---|
| Read | 2-3 | V | 0.6-2 | V | 0 | V |
| Erase | ~11-13 | V | 0 | V | 0 | V |
| Program | 1-2 | V | 1-5 | μA | 9-10 | V |

Other split gate memory cell configurations, which are other types of flash memory cells, are known. For example, FIG. 3 depicts a four-gate memory cell 310 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source.

Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 310 for performing read, erase, and program operations:

TABLE NO 2
Operation of Flash Memory Cell 310 of FIG. 3

| | WL/SG | | BL | | CG | | EG | | SL | |
|---|---|---|---|---|---|---|---|---|---|---|
| Read | 0.7-3 | V | 0.5-2 | V | 0-3 | V | 0-3 | V | 0 | V |
| Erase | 0 | V | 0 | V | 0 V/−8 V | | 8-13 | V | 0 | V |
| Program | 0.6-1.2 | V | 0.1-2 | μA | 8-12 | V | 4-9 | V | 4-5 | V |

FIG. 4 depicts a three-gate memory cell 410, which is another type of flash memory cell. Memory cell 410 is identical to the memory cell 310 of FIG. 3 except that memory cell 410 does not have a separate control gate. The erase operation (whereby erasing occurs through use of the erase gate) and read operation are similar to that of the FIG. 3 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 410 for performing read, erase, and program operations:

TABLE NO 3
Operation of Flash Memory Cell 410 of FIG. 4

| | WL/SG | | BL | | EG | | SL | |
|---|---|---|---|---|---|---|---|---|
| Read | 0.7-3 | V | 0.5-2 | V | 0-3 | V | 0 | V |
| Erase | 0 | V | 0 | V | 11-13 | V | 0 | V |
| Program | 0.6-1.2 | V | 0.2-5 | μA | 3-6 | V | 6-10 | V |

FIG. 5 depicts stacked gate memory cell 510, which is another type of flash memory cell. Memory cell 510 is similar to memory cell 210 of FIG. 2, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 510 and substrate 12 for performing read, erase, and program operations:

TABLE NO 4
Operation of Flash Memory Cell 510 of FIG. 5

| | CG | | BL | | SL | | Substrate | |
|---|---|---|---|---|---|---|---|---|
| Read | 2-5 | V | 0.5-2 | V | 0 | V | 0 | V |
| Erase | −8 to −10 V/0 V | | float | | float | | 8-10 V/15-20 V | |
| Program | 8-12 | V | 3-7 | V | 0 | V | 0 | V |

Flash memory cells such as cells 210, 310, 410, and 510 in FIGS. 2, 3, 4, and 5, respectively, are capable of storing one bit of data in a “single-level cell” (SLC) format (i.e., an SLC memory cell is one operated in the SLC mode to store 1 bit of data in the SLC format) or storing more than one bit of data in “multi-level cell” (MLC) format (i.e., an MLC memory cell is one that is operated in the MLC mode to store more than one bit of data in the MLC format). In one approach, the stored bits are determined by applying certain voltages to terminals of the cell and reading the resulting current, referred to as a read current, and comparing the read current against one or more reference currents using a sense amplifier. A sense amplifier for an SLC format might use a single reference current, where a read current greater than the reference current indicates a bit value of a first value (e.g., a “1”) and a read current less than the reference current indicates a bit value of a second value (e.g., a “0”). A sense amplifier for an MLC format might use multiple reference currents. For example, an MLC format with four possible levels might use three reference currents of different values, where the bit values are determined based on the relative size of the read current against each of the three reference currents. For example, if the reference currents are Ia, Ib, and Ic where Ia<Ib<Ic, a read current less than Ia might indicate bit values of a first value (e.g., “00”), a read current between Ia and Ib might indicate bit values of a second value (e.g., “01”), a read current between Ib and Ic might indicate bit values of a third value (e.g., “10”), and a read current greater than Ic might indicate bit values of a fourth value (e.g., “11”). It is to be understood that an MLC format is not limited to this example of 4 levels and can have 8 levels, 16 levels, 32 levels, or more.

An MLC memory cell can store more data than an SLC memory cell for the same die space but an MLC memory cell takes longer than an SLC memory cell to program and verify. An MLC memory cell also has a smaller read window than an SLC memory cell, which makes an MLC memory cell more sensitive than an SLC memory cell to charge state drift over its data retention lifetime. Charge state drift can result in an error if not corrected. The same memory cell can be operated in MLC mode at one point in time, and operated in SLC mode at a different point in time, depending on the needs of a particular application.

The methods and means described herein may apply to other non-volatile memory technologies that are capable of operating in SLC and MLC modes, such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

What is needed are improved methods for storing and updating software code in a non-volatile storage device in a system while the system is operating in a way that utilizes the benefits of SLC memory cells and MLC memory cells.

### BRIEF SUMMARY OF THE INVENTION

The aforementioned problems and needs are addressed by a method comprising, storing (n−1) partitions of a first image of code in a first set of banks in single-level cell format, wherein the first set of banks comprise (n−1) of n banks of flash memory cells, and storing (n−1) partitions of the first image as first significant bits and (n−1) partitions of a second image of code as second significant bits in a second set of banks in dual step multi-level cell format, wherein the second set of banks comprise (n−1) of the n banks and the second set of banks comprises a bank not contained in the first set of banks, and wherein the first significant bits are either least significant bits or most significant bits of the flash memory cells, and the second significant bits are the other of the least significant bits and the most significant bits of the flash memory cells.

A method comprises storing (n−1) partitions of a first image of code as first significant bits in a first set of banks in dual step multi-level cell format, wherein the first set of banks comprise (n−1) of n banks of flash memory cells, and storing (n−1) partitions of a second image of code as second significant bits in the first set of banks in dual step multi-level cell format, wherein the first significant bits are either least significant bits or most significant bits of the flash memory cells, and the second significant bits are the other of the least significant bits and the most significant bits of the flash memory cells.

A system comprises n banks of flash memory cells and circuitry to store (n−1) partitions of a first image of code in a first set of banks in single-level cell format, wherein the first set of banks comprise (n−1) of the n banks of flash memory cells, and store (n−1) partitions of the first image as first significant bits and (n−1) partitions of a second image of code as second significant bits in a second set of banks in dual step multi-level cell format, wherein the second set of banks comprise (n−1) of the n banks and the second set of banks comprises a bank not contained in the first set of banks, and wherein the first significant bits are either least significant bits or most significant bits of the flash memory cells, and the second significant bits are the other of the least significant bits and the most significant bits of the flash memory cells.

A system comprises n banks of flash memory cells and circuitry to store (n−1) partitions of a first image of code as first significant bits in a first set of banks in dual step multi-level cell format, wherein the first set of banks comprise (n−1) of the n banks of flash memory cells, and store (n−1) partitions of a second image of code as second significant bits in the first set of banks in dual step multi-level cell format, wherein the first significant bits are either least significant bits or most significant bits of the flash memory cells, and the second significant bits are the other of the least significant bits and the most significant bits of the flash memory cells.

Other objects and features of the present disclosure will become apparent by a review of the specification, claims and appended figures.

### BRIEF DESCRIPTION OF THE DRAWINGS

FIG. 1 depicts a system comprising code stored in non-volatile storage.

FIG. 2 depicts a split-gate flash memory cell.

FIG. 3 depicts a split-gate flash memory cell.

FIG. 4 depicts a split-gate flash memory cell.

FIG. 5 depicts a stacked-gate flash memory cell.

FIG. 6 depicts non-volatile storage comprising a plurality of banks.

FIG. 7 depicts an image of code divided into partitions.

FIGS. 8A and 8B depict an example of an algorithm for storing images of code in non-volatile storage.

FIGS. 9A and 9B depict an example of an algorithm for storing images of code in non-volatile storage.

FIG. 10 depicts an example of an algorithm for storing images of code in non-volatile storage.

FIG. 11 depicts an example of an algorithm for storing images of code in non-volatile storage.

FIGS. 12-13 depict the SLC format program states.

FIGS. 14-15 depict the MLC format program states.

FIG. 16 depicts DS-MLC format first partition programming.

FIG. 17 depicts DS-MLC format second partition programming.

FIGS. 18A and 18B depict an example of an algorithm for storing images of code in non-volatile storage.

FIGS. 19A and 19B depict an example of an algorithm for storing images of code in non-volatile storage.

### DETAILED DESCRIPTION OF THE INVENTION

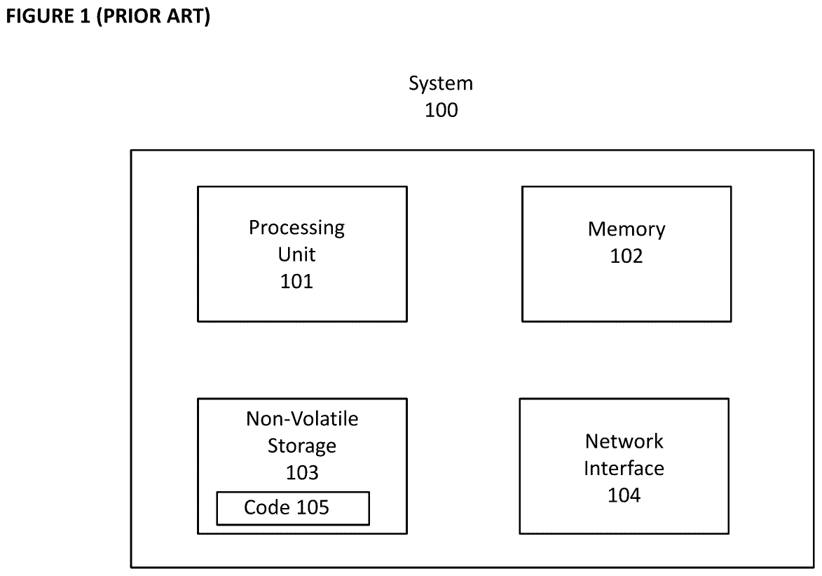

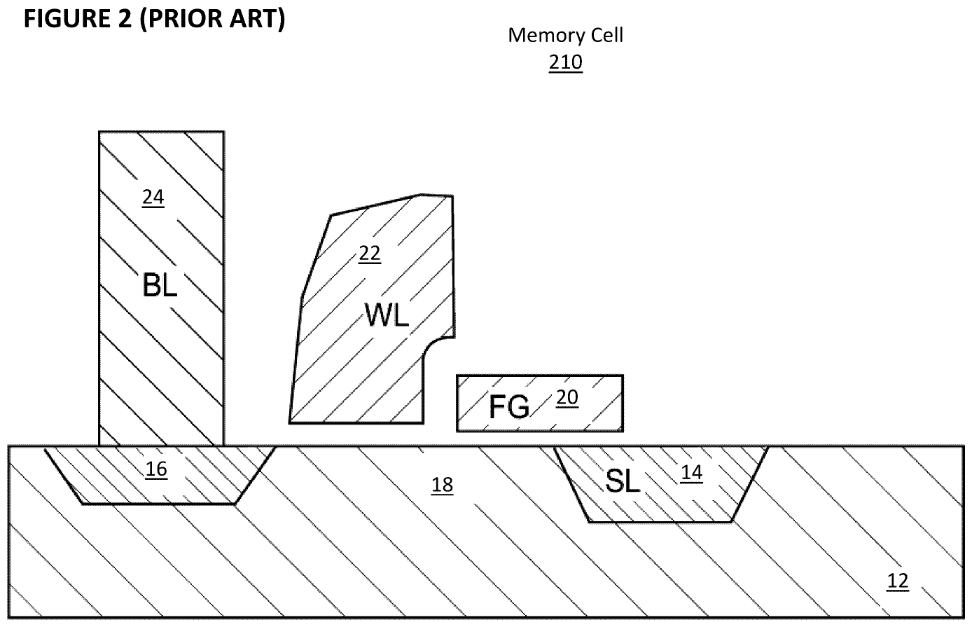

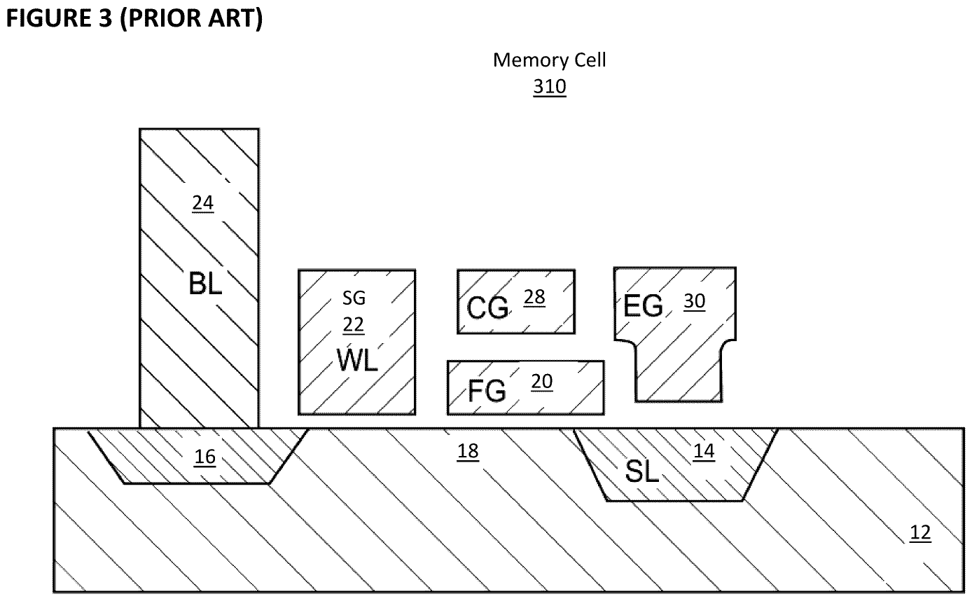

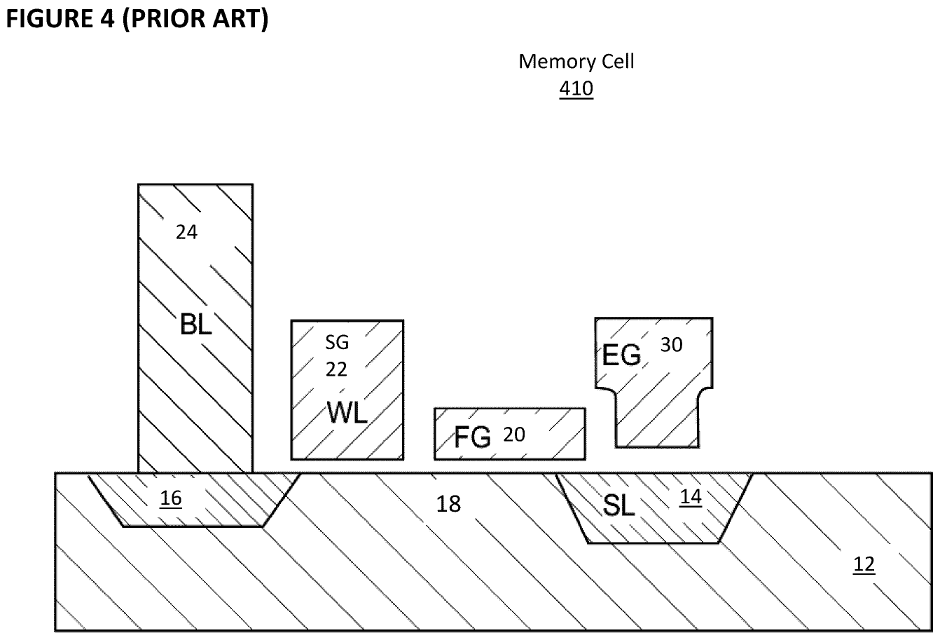

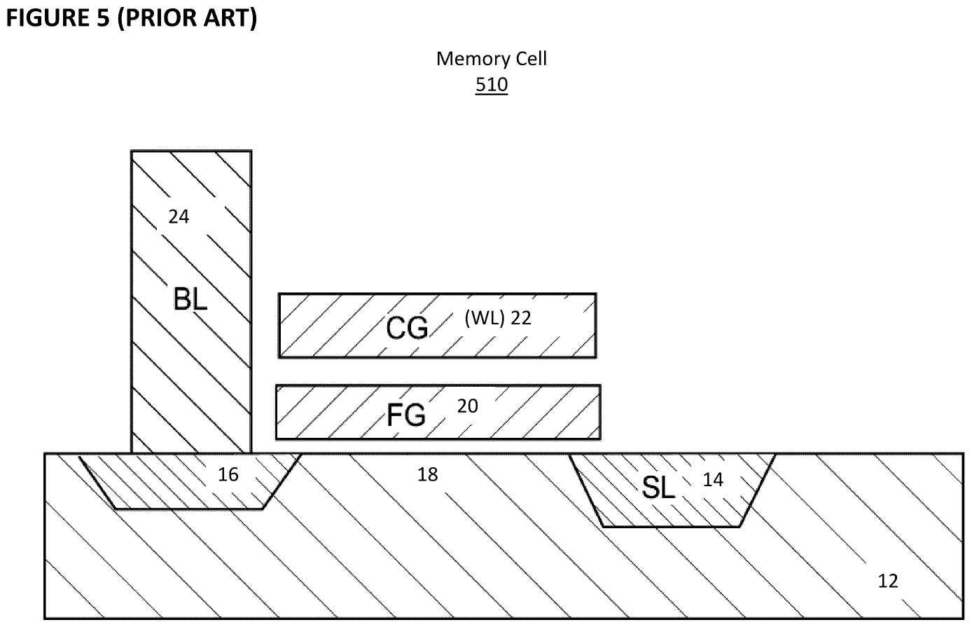

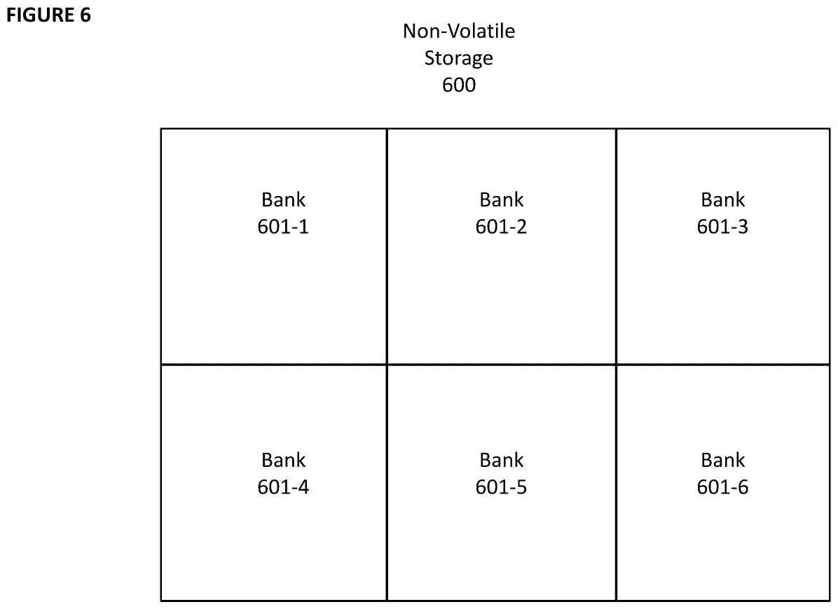

FIG. 6 depicts non-volatile storage 600, which is an example of non-volatile storage 103 in system 100 of FIG. 1. Non-volatile storage 600 comprises a plurality of banks, specifically, banks 601-1, 601-2, 601-3, 601-4, 601-5, and 601-6. It is to be understood that non-volatile storage 600 can comprise a greater or lesser number of banks. Each bank comprises one or more physical arrays of non-volatile memory cells arranged in rows and columns. The non-volatile memory cells can be flash memory cells of the type shown in FIGS. 2-5 as memory cells 210, 310, 410, and 510, respectively, or another type of memory cell.

Processing unit 101 includes circuitry that implements the data storage techniques described herein. The circuitry of processing unit 101 may be loaded with software, i.e. non-transitory electronically readable instructions, or firmware, or can consist of respective circuits, or any combination thereof, to perform the methods described herein. The circuitry of processing unit 101 can be implemented by a microcontroller, dedicated circuitry, a processor, a general purpose processor running firmware or software, or a combination thereof.

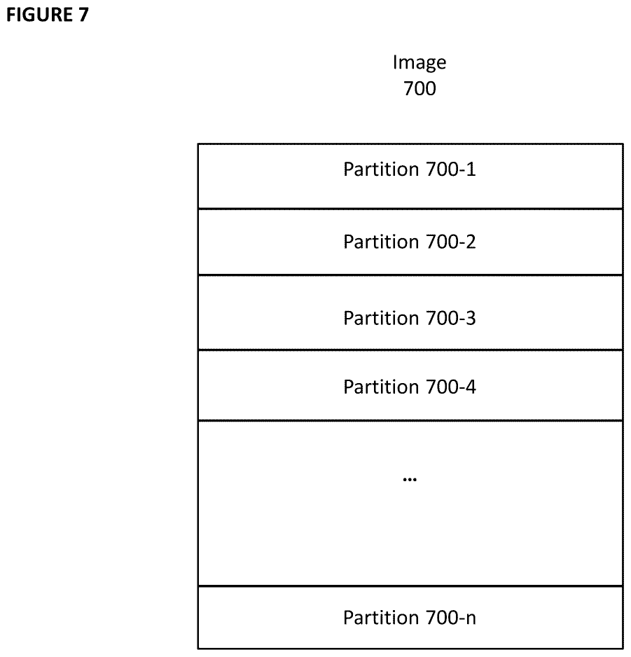

FIG. 7 depicts image 700, which is an example of code 105 in system 100 of FIG. 1. Image 700 can comprise, for example, an executable version of a software application executed by processing unit 101 of system 100. In this example, image 700 is stored in n different partitions, here, partitions 700-1, 700-2, 700-3, 700-4, . . . , 700-n. It is to be understood that image 700 might instead be stored in a greater or lesser number of partitions depending on its overall size and other considerations.

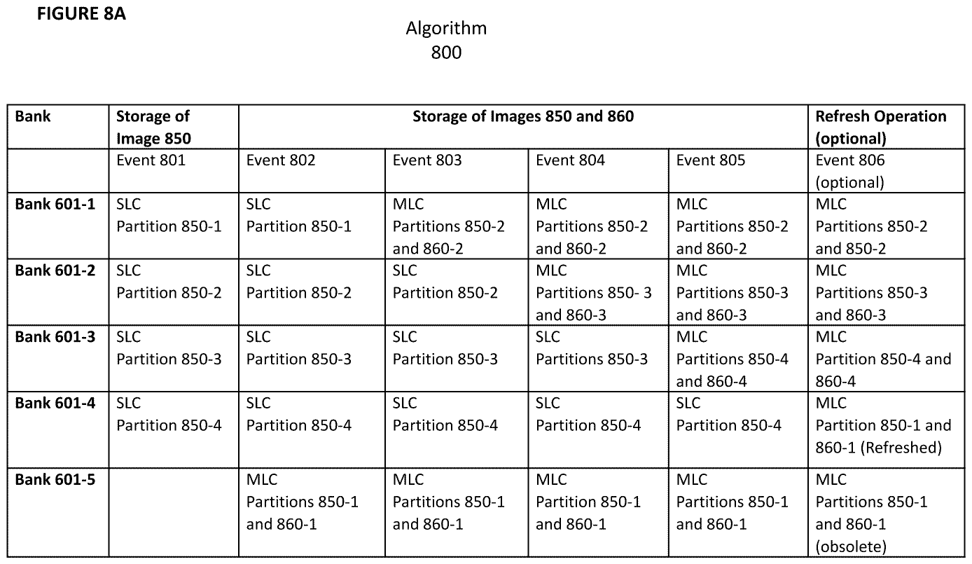

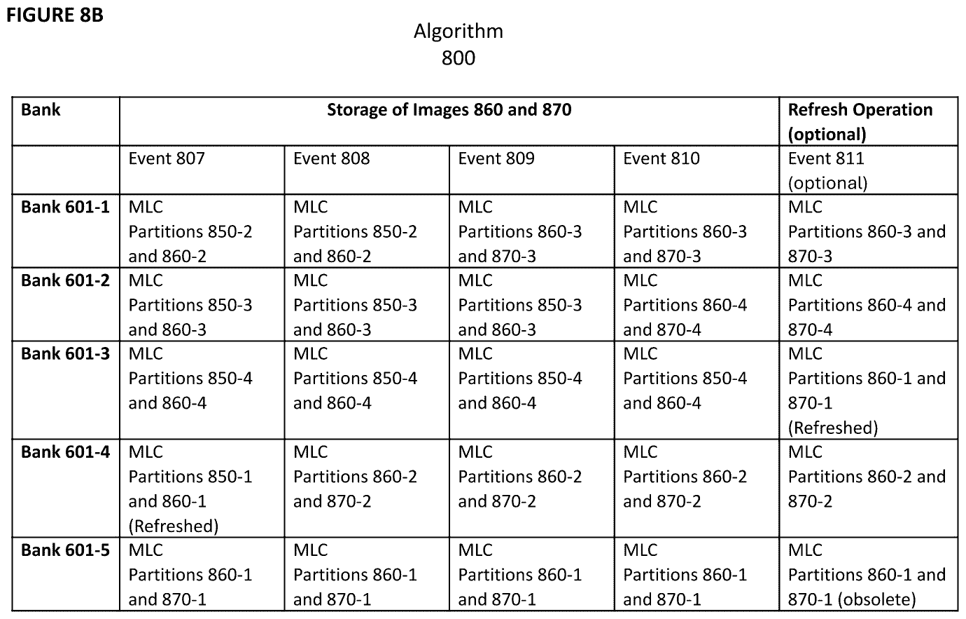

FIGS. 8A, 8B, 9A, 9B, 10, and 11 describe algorithms that can be implemented in code stored in non-volatile storage 103, loaded into memory 102, and implemented by processing unit 101 in system 100 in FIG. 1. These algorithms are utilized to store and update other code (such as code 105) in non-volatile storage 103. These algorithms comprise methods performed by system 100.

FIGS. 8A and 8B depict algorithm 800, which comprises an example sequence of events to store images 850, 860 and 870 in system 100, which are examples of image 700 in FIG. 7, in non-volatile storage 600 of FIG. 6. Algorithm 800 stores images 850, 860, and 870 in banks 601-1, 601-2, 601-3, 601-4, and 601-5.

Event 801 is the initial loading of code during the manufacturing process. Image 850 is stored as partitions 850-1, 850-2, 850-3, and 850-4 in banks 601-1, 601-2, 601-3, and 601-4, respectively, using SLC format storage (i.e., the memory cells are programmed to store these partitions in SLC format). The benefit of using SLC format instead of MLC format during manufacturing is that the programming process is faster for SLC format than MLC format and using SLC format for event 801 will decrease manufacturing time. SLC format is also less susceptible to read errors in the event of some charge state drift.

Event 802 is the beginning of a code update, such as an OTA update, that occurs when system 100 is operating in the field. Specifically, image 860 is to be stored, beginning with partition 860-1 during event 802. It is desired to maintain a copy of image 850 while image 860 is being stored. Partitions 850-1 and 860-1 are stored in bank 601-5 using MLC format storage. Because banks 601-1, 601-2, 601-3, and 601-4 already contain the entirety of image 850, system 100 can store 850-1 and 860-1 using MLC format storage because there is no time-pressure to complete the operation since image 850 is available for the system to use. The greater density of the MLC format enables bank 605-1 to store both partitions 850-1 and 860-1 even in the situation where either of those portions would fill nearly the entirety of bank 605-1 when SLC format storage is used.

In event 803, another portion of image 860 is stored. Partitions 850-2 and 860-2 are stored in bank 601-1 using MLC format storage.

In event 804, another portion of image 860 is stored. Partitions 850-3 and 860-3 are stored in bank 601-2 using MLC format storage.

In event 805, another portion of image 860 is stored. Partitions 850-4 and 860-4 are stored in bank 601-3 using MLC format storage. At the conclusion of event 805, banks 601-1, 601-2, 601-3, and 601-5 collectively contain the entirety of images 850 and 860.

Periodically, system 100 performs safety read operations to detect possible charge state drift within banks 601-1, 601-2, 601-3, and 601-5 where one or more memory cells are no longer storing the intended charge state, and determine if a data refresh is needed to correct the drift and prevent system malfunction. This safety read can be performed using a more stringent read condition that that used in code execution (user read), or using an error correction code (ECC) engine during a user read operation. After a certain amount of charge state drift errors have been detected, system 100 can perform a refresh operation whereby data is copied from a first bank, error correction is performed, and the corrected data is stored in a second bank, which will enable code to continue to be executed from the first bank while the refresh operation is performed. In optional event 806, a refresh operation is performed. In this example, a charge state drift error has been detected in partitions 850-1 or 860-1. It is to be understood that the charge state drift error can occur and be detected in any partition and that partitions 850-1 and 860-1 here are used as an example. The system copies the data for partitions 850-1 and 860-1 from bank 601-5, performs error correction on the data, and stores the refreshed data for partitions 850-1 and 860-1 in bank 601-4. Thereafter, refreshed partitions 850-1 and 860-1 are executed from bank 601-4, and the data in bank 601-5 is deemed obsolete.

Event 807 is the beginning of another code update, such as an OTA update, that occurs when the system is in the field. Specifically, image 870 is to be stored, beginning with partition 870-1 during event 807. Image 850 is obsolete because image 860 is now being executed and image 850 will be overwritten beginning with event 807. It is desired to maintain a copy of image 860 while image 870 is being stored. Partitions 860-1 and 870-1 are stored in bank 601-5 using MLC format storage. Because banks 601-1, 601-2, 601-3, and 601-4 already contain the entirety of image 860, system 100 can store 860-1 and 870-1 using MLC format storage because there is no time-pressure to complete the operation since image 860 is available for the system to use. The greater density of MLC format enables bank 601-5 to store both partitions 860-1 and 870-1 even in the situation where either of those portions would fill nearly the entirety of bank 605-1 when SLC format storage is used.

In event 808, another portion of image 870 is stored. Partitions 860-2 and 870-2 are stored in bank 601-4 using MLC format storage.

In event 809, another portion of image 870 is stored. Partitions 860-3 and 870-3 are stored in bank 601-1 using MLC format storage.

In event 810, another portion of image 870 is stored. Partitions 860-4 and 870-4 are stored in bank 601-2 using MLC format storage.

In optional event 811, another refresh operation is performed after a charge state drift error is detected in partitions 860-1 or 870-1. It is to be understood that the charge state drift error can occur and be detected in any partition and that partitions 860-1 and 870-1 here are used as an example. The system copies the data for partitions 860-1 and 870-1 from bank 601-5, performs error correction on the data, and stores the refreshed data for partitions 860-1 and 870-1 in bank 601-3.

More generally, one portion of algorithm 800 can be characterized as storing (n−1) partitions of a first image of code in a first set of banks in single-level cell format, wherein the first set of banks comprise (n−1) of n banks of flash memory cells; and storing (n−1) partitions of the first image and (n−1) partitions of a second image of code in a second set of banks in multi-level cell format, wherein the second set of banks comprise (n−1) of the n banks and the second set of banks comprises a bank not contained in the first set of banks.

Another portion of algorithm 800 can be characterized as storing (n−1) partitions of a first image and (n−1) partitions of a second image of code in a first set of banks in multi-level cell format, wherein the first set of banks comprises (n−1) of n banks of flash memory cells; and storing (n−1) partitions of the second image and (n−1) partitions of a third image of code in a second set of banks in multi-level cell format, wherein the second set of banks comprise (n−1) of the n banks and the second set of banks comprises a bank not contained in the first set of banks.

Additional OTA updates and refresh operations can be performed throughout the lifetime of system 100 using the principles described above for algorithm 800.

Thus, algorithm 800 maintains two images beginning when the first code update is complete. It allows for data to be refreshed at any time, as there can always be either one image of factory code, one image of the factory code with one image of the OTA code, or two images of OTA code that can be used. Algorithm 800 can perform wear leveling within the various banks. All banks experience on average 80% of an MLC erase and program cycle during each code update (as 4 of 5 banks are involved in each code update) and 20% of an MLC erase and program cycle per refresh operation (as 1 of 5 banks are involved in each code update).

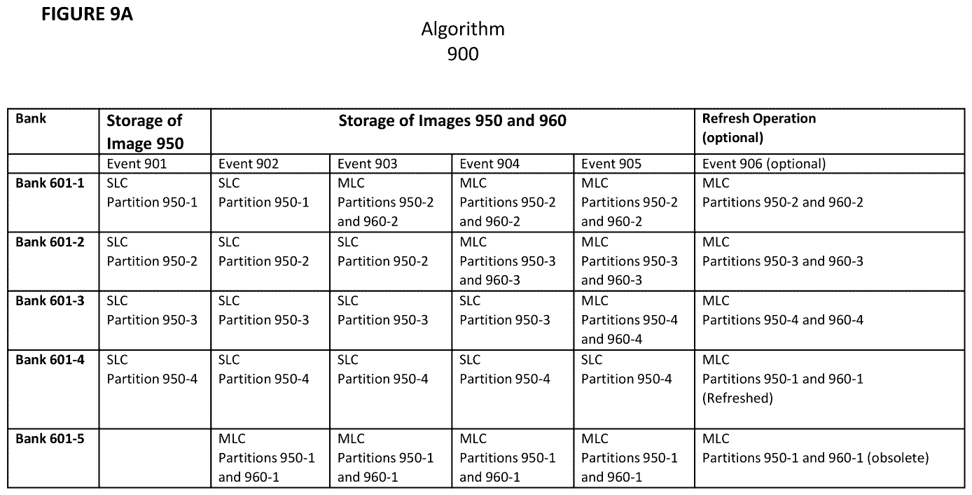

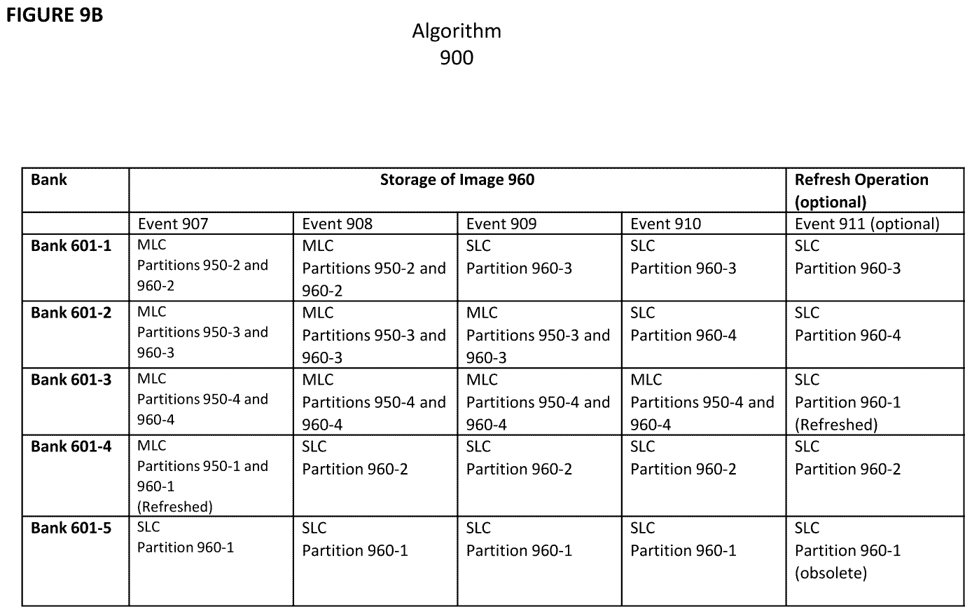

FIGS. 9A and 9B depict algorithm 900, which comprises an example sequence of events to store images 950 and 960, which are examples of image 700 in FIG. 7, in non-volatile storage 600 of FIG. 6. Algorithm 900 stores images 950 and 960 in banks 601-1, 601-2, 601-3, 601-4, and 601-5.

Event 901 is the initial loading of code during the manufacturing process. Image 950 is stored as partitions 950-1, 950-2, 950-3, and 950-4 in banks 601-1, 601-2, 601-3, and 601-4, respectively, using SLC format storage. The benefit of using SLC format instead of MLC format during manufacturing is that the programming process is faster for SLC format than MLC format and using SLC format for event 801 will decrease manufacturing time. SLC format is also less susceptible to read errors in the event of some charge state drift.

Event 902 is the beginning of a code update, such as an OTA update, that occurs when the system is in the field. Specifically, image 960 is to be stored, beginning with partition 960-1 during event 902. It is desired to maintain a copy of image 950 while image 960 is being stored. Partitions 950-1 and 960-1 are stored in bank 601-5 using MLC format storage. Because banks 601-1, 601-2, 601-3, and 601-4 already contain the entirety of image 950, system 100 can store 950-1 and 960-1 using MLC format storage because there is no time-pressure to complete the operation since image 950 is available for the system to use. The greater density of MLC format enables bank 605-1 to store both partitions 950-1 and 960-1 even in the situation where either of those portions would fill nearly the entirety of bank 605-1 when SLC format storage is used.

In event 903, another portion of image 960 is stored. Partitions 950-2 and 960-2 are stored in bank 601-2 using MLC format storage.

In event 904, another portion of image 960 is stored. Partitions 950-3 and 960-3 are stored in bank 601-2 using MLC format storage.

In event 905, another portion of image 960 is stored. Partitions 950-4 and 960-4 are stored in bank 601-3 using MLC format storage. At the conclusion of event 905, banks 601-1, 601-2, 601-3, and 601-5 collectively contain the entirety of images 950 and 960.

In optional event 906, a refresh operation is performed after a charge state drift error is detected in partitions 950-1 or 960-1. It is to be understood that the charge state drift error can occur and be detected in any partition and that partitions 950-1 and 960-1 here are used as an example. The system copies the data for partitions 950-1 and 960-1 from bank 601-5, performs error correction on the data, and stores the refreshed data for partitions 950-1 and 960-1 in bank 601-4.

Event 907 is the beginning of a conversion process whereby image 960 will be stored in SLC format instead of MLC format. This can be useful because data in SLC format is less susceptible to data drift errors due to charge state drift. It is desired to maintain a copy of image 960 at all times so that it can still be executed. Partition 960-1 is stored in bank 601-5 using SLC format storage.

In event 908, another portion of image 960 is stored in SLC format. Partition 960-2 is stored in bank 601-4 using SLC format storage.

In event 909, another portion of image 960 is stored in SLC format. Partition 960-3 is stored in bank 601-1 using SLC format storage.

In event 910, another portion of image 960 is stored in SLC format. Partition 960-4 is stored in bank 601-2 using SLC format storage.

In optional event 911, another refresh operation is performed after a charge state drift error is detected in partition 960-1. It is to be understood that the charge state drift error can occur and be detected in any partition and that partition 960-1 here is used as an example. The system copies the data for partition 960-1 from bank 601-5, performs error correction on the data, and stores the refreshed data for partition 960-1 in bank 601-3.

More generally, one portion of algorithm 900 can be characterized as storing (n−1) partitions of a first image of code in a first set of banks in single-level cell format, wherein the first set of banks comprises (n−1) of n banks of flash memory cells; and storing (n−1) partitions of the first image and (n−1) partitions of a second image of code in a second set of banks in multi-level cell format, wherein the second set of banks comprise (n−1) of the n banks and the second set of banks comprises a bank not contained in the first set of banks. Algorithm 900 can further comprise storing the (n−1) partitions of the second image of code in a third set of banks in single-level cell format, wherein the third set of banks comprise (n−1) of the n banks and the third set of banks comprises a bank not contained in the second set of banks.

Another portion of algorithm 900 can be characterized as storing (n−1) partitions of a first image and (n−1) partitions of a second image of code in a first set of banks in multi-level cell format, wherein the first set of banks comprises (n−1) of n banks of flash memory cells; and storing the (n−1) partitions of the second image of code in a second set of banks in single-level cell format, wherein the second set of banks comprise (n−1) of the n banks and the second set of banks comprises a bank not contained in the first set of banks.

Additional OTA updates and refresh operations can be performed throughout the lifetime of system 100 using the principles described above for algorithm 900.

Thus, algorithm 900 maintains one image of factory code, two images during OTA code updates and for a flexible period afterward, during which new image can be validated, and one image of OTA code after its validation is complete. It allows for data to be refreshed at any time, as there can always be either one or two images that can be used. Long-term storage will use SLC format, which has a higher reliability than MLC format due to lesser susceptibility to charge state drift. Algorithm 900 performs wear leveling. The banks will experience greater wear compared to algorithm 800. All banks experience on average 80% of an MLC erase and program cycle and 80% of an SLC erase and program cycle during each code update (as 4 of 5 banks are involved in each code update) and 20% of an MLC erase and program cycle or an SLC erase and program cycle per refresh operation (as 1 of 5 banks are involved in each code update).

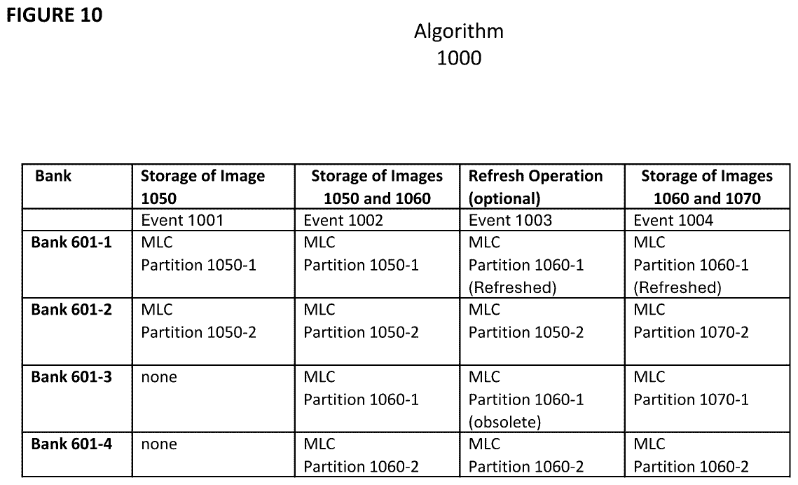

FIG. 10 depicts algorithm 1000, which comprises an example sequence of events to store images 1050 and 1060, which are examples of image 700 in FIG. 7, in non-volatile storage 600 of FIG. 6. Algorithm 1000 stores images 1050, 1060, and 1070 in banks 601-1, 601-2, 601-3, and 601-4. Thus, algorithm 1000 utilizes less die space (4 banks) than algorithms 800 and 900 of FIGS. 8A, 8B, 9A, and 9B (5 banks).

Event 1001 is the initial loading of code during the manufacturing process. Image 1050 is stored as partitions 1050-1 and 1050-2 in banks 601-1 and 601-2, respectively, using MLC format storage, which will take more time for the programming process compared to a situation where SLC format is used instead.

Event 1002 is a code update, such as an OTA update, that occurs when the system is in the field. Specifically, image 1060 is to be stored. It is desired to maintain a copy of image 1050 while image 1060 is being stored. Partition 1060-1 is stored in bank 601-3 using MLC format storage, and partition 1060-2 is stored in bank 601-4 using MLC format storage. Because banks 601-1 and 601-2 already contain the entirety of image 1050, system 100 can store 1060-1 and 1060-2 using MLC format storage because there is no time-pressure to complete the operation since image 1050 is available for the system to use.

In optional event 1003, a refresh operation is performed after a data drift error is detected in partition 1060-1. It is to be understood that the data drift error can occur and be detected in any partition and that partition 1060-1 here is used as an example. The system copies the data for partition 1060-1 from bank 601-3, performs error correction on the data, and stores the refreshed data for partition 1060-1 in bank 601-1.

Event 1004 is another code update, such as an OTA update, that occurs when the system is in the field. Specifically, image 1070 is to be stored. It is desired to maintain a copy of image 1060 while image 1070 is being stored. Partition 1070-1 is stored in bank 601-3 using MLC format storage, and partition 1070-2 is stored in bank 601-2 using MLC format storage. Because banks 601-1 and 601-4 already contain the entirety of image 1060, system 100 can store 1070-1 and 1070-2 using MLC format storage because there is no time-pressure to complete the operation since image 1070 is available for the system to use.

More generally, one portion of algorithm 1000 can be characterized as storing (n/2) partitions of a first image of code in a first set of banks in multi-level cell format, wherein the first set of banks comprise n/2) of the n banks; and storing (n/2) partitions of a second image of code in a second set of banks in multi-level cell format, wherein the second set of banks comprise (n/2) of the n banks and the banks in the second set of banks are not contained in the first set of banks.

Additional OTA updates and refresh operations can be performed throughout the lifetime of system 100 using the principles described above for algorithm 1000.

Thus, algorithm 1000 maintains two images beginning when the first code update is complete during the code update and validation periods. It allows for data to be refreshed outside of the code update and validation period. Algorithm 1000 performs wear leveling. The wear will be better than for algorithms 800 and 900. All banks experience on average 50% of an MLC erase and program cycle during each code update (as 2 of 4 banks are involved in each code update) and 25% of an MLC erase and program cycle per refresh operation (as 1 of 4 banks are involved in each refresh).

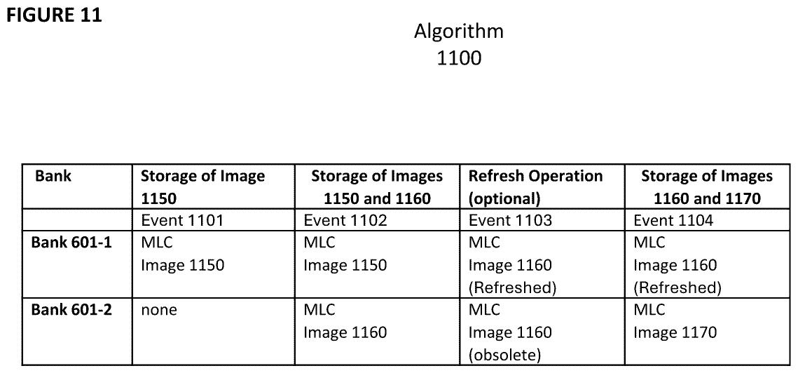

FIG. 11 depicts algorithm 1100, which comprises an example sequence of events to store images 1150, 1160, and 1170, which are examples of image 700 in FIG. 7, in non-volatile storage 600 of FIG. 6. Algorithm 1100 stores images 1150, 1160, and 1170 in banks 601-1, 601-2, 601-3, 601-4, and 601-5.

Event 1101 is the initial loading of code during the manufacturing process. Image 1150 is in its entirety in bank 601-1 using MLC format storage, which will take more time for the programming process compared to a situation where SLC format is used instead.

Event 1102 is a code update, such as an OTA update, that occurs when the system is in the field. Specifically, image 1160 is to be stored. It is desired to maintain a copy of image 1150 while image 1160 is being stored. Image 1160 is stored in its entirety in bank 601-2 using MLC format storage. Because banks 601-1 already contains the entirety of image 1150, system 100 can store image 1160 using MLC format storage because there is no time-pressure to complete the operation since image 1150 is available for the system to use.

In optional event 1103, a refresh operation is performed after a data drift error is detected in image 1160. The system copies the data for image 1160 from bank 601-2, performs error correction on the data, and stores the refreshed data for image in bank 601-1.

Event 1104 is another code update, such as an OTA update, that occurs when the system is in the field. Specifically, image 1170 is to be stored. It is desired to maintain a copy of image 1160 while image 1170 is being stored. Image 1170 is stored in its entirety in bank 601-2 using MLC format storage. Because banks 601-1 already contains the entirety of image 1160, system 100 can store image 1170 using MLC format storage because there is no time-pressure to complete the operation since image 1160 is available for the system to use.

More generally, one portion of algorithm 1100 can be characterized as storing a first image of code in a first bank of flash memory cells in multi-level cell format; and storing a second image of code in a second bank of flash memory cells in multi-level cell format.

Additional OTA updates and refresh operations can be performed throughout the lifetime of system 100 using the principles described above for algorithm 800.

Thus, algorithm 1100 maintains two images beginning when the first code update is complete during the code update and validation periods. It allows for data to be refreshed outside of the code update and validation period. Algorithm 1100 performs wear leveling. The wear will be better than for algorithms 800 and 900. All banks experience on average 50% of an MLC erase and program cycle during each code update (as 1 of 2 banks are involved in each code update) and 50% of an MLC erase and program cycle per refresh operation (as 1 of 2 banks are involved in each refresh).

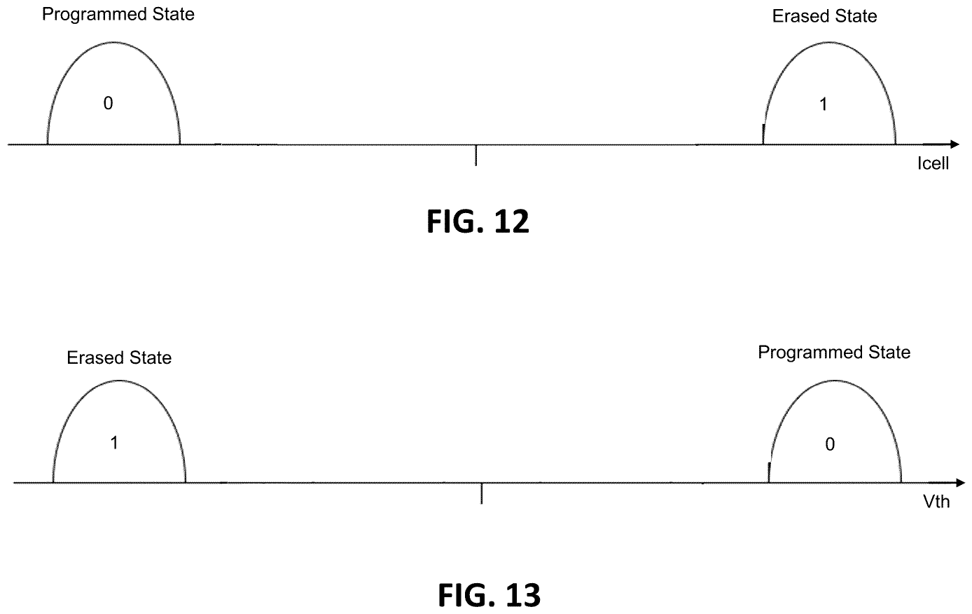

In another example, dual step multi-level cell format (DS-MLC) can be used instead of MLC format to store code updates. The differences between SLC, MLC and DS-MLC formats are illustrated in FIGS. 12-17. FIGS. 12 and 13 show the SLC format program states for a memory cell storing 1 bit (i.e., using two possible program states: programmed and erased) as a function of cell current Icell (FIG. 12) or threshold voltage Vth (FIG. 13) during a read operation. As shown in FIGS. 12 and 13, the program and erase operations result in a distribution of cell current Icell and threshold voltage Vth for each program state given these operations are not perfectly precise. The fully erased program state 1 provides the highest cell current Icell (as shown in FIG. 12), and the lowest threshold voltage Vth (as shown in FIG. 13) during a read operation (where threshold voltage Vth refers to the minimum value for one of the read voltages applied during a read operation to obtain a threshold read current). Conversely, the programmed state 0 provides the lowest cell current Icell (as shown in FIG. 12), and the highest threshold voltage Vth (as shown in FIG. 13) during a read operation. SLC format is advantageous because the separation between the two program states is greater than that of MLC format, and therefore small changes in the program states due to charge state drift can be tolerated without causing a read error.

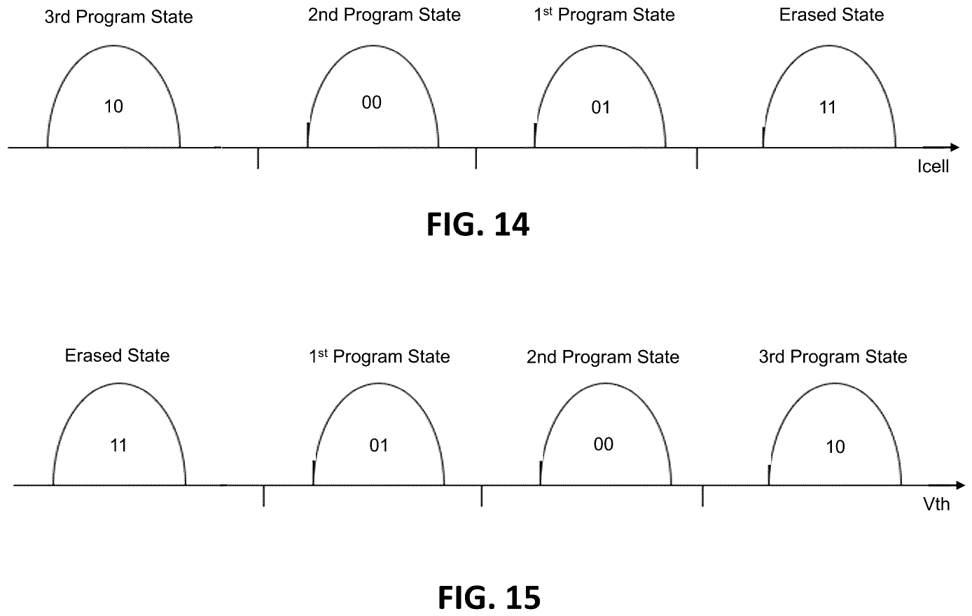

FIGS. 14 and 15 show the MLC format program states for a memory cell storing 2 bits of information (i.e., using four possible program states) as a function of cell current Icell (FIG. 14) or threshold voltage Vth (FIG. 15) during a read operation. The erased state 11 corresponds to the distribution of lowest threshold voltages Vth and highest cell currents Icell for the erased memory cells. The first program state 01 corresponds to the distribution of next highest threshold voltages Vth and next lowest cell currents Icell for memory cells programmed to the first program state 01. The second program state 00 corresponds to the distribution of next highest threshold voltages Vth and next lowest cell currents Icell for memory cells programmed to the second program state 00. The third program state 10 corresponds to the distribution of next highest threshold voltages Vth and the next lowest cell currents Icell for memory cells programmed to the third program state 10. The respective distributions of threshold voltages Vth (as well as corresponding distributions of read currents Icell) for the respective program states can also be referred to as program state distributions. As used herein, the higher the number of electrons on the floating gate, the higher the program state. Therefore, the fully programmed state 10 is the highest program state, and the erased state 11 is the lowest program state.

In SLC format, two bits (e.g., two consecutive bits) from the same image partition are stored in two memory cells (i.e., one bit in each memory cell). For example, if the next two bits to be stored in a given partition are 01, they are stored in the first memory cell in the programmed state (0) and in the second memory cell in the erased state (1). In MLC format, two bits (e.g., two consecutive bits) from the same image partition are stored in 1 memory cell. For example, if the next two bits to be stored in a given partition are 01, then they are stored in the one memory cell in the first programmed state (01). In both cases, a pair of memory cells in SLC format, or a single memory cell in MLC format, are or is used to store two bits (e.g., two consecutive bits) from the same image partition.

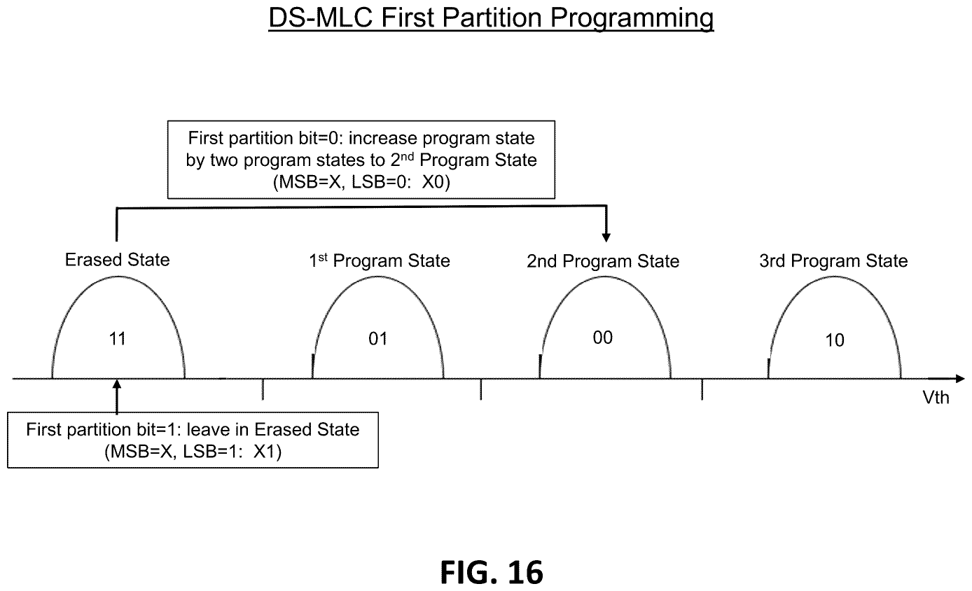

In contrast, a Dual Step MLC (DS-MLC) format is disclosed that stores two bits of information from two different image partitions, and even from two images, in a single memory cell. For simplicity, the discussion going forward is directed to threshold voltage Vth and not also of read current Icell, but the following could be described in terms of read current Icell as well, as one is the inverse of the other (i.e., as threshold voltage Vth rises at higher program states, read current Icell falls, and vice versa). As shown in FIG. 16, DS-MLC format programming to a memory cell can begin with the memory cells in their erased state (11). For the purposes of this disclosure, for the two bit values represented by “11”, the first bit can be referred to as the most significant bit (MSB) and the second bit can be referred to as the least significant bit (LSB). Therefore, the bit values shown in FIGS. 14-17 have the following format: MSB, LSB. As an example, for the first program state 01, the MSB is 0 and the LSB is 1. Starting with the memory cells in the erased state, the memory cells begin DS-MLC format programming with MSB and LSB both being 1.

As shown in FIG. 16, at the time of programming a bit (e.g., 0 or 1) from a first partition to a memory cell, the bit to be programmed from a second partition is unknown (e.g., X). Programming the bit from the first partition involves the LSB. If the bit being programmed from the first partition is LSB=1, the memory cell is left in its erased state (representing X1 at this stage), and if the bit being programmed from the first partition is LSB=0, then the memory cell is programmed to increase its program state by two program states to the second program state (representing X0 at this stage) (i.e., increase the program state from the erased state to the second program state, skipping over the first program state), as shown in FIG. 16. At this point, the bit from the first partition is stored in the memory cell in a pseudo SLC format that does not include fully programming the memory cells, where a second bit of information can later be added to the memory cell by further programming. At this point, with the LSB known (i.e., 0 or 1), but the MSB unknown (i.e., X), the data stored in the memory cell can represent X1 or X0. Programming of all the first partition bits to memory cells can be performed as set forth above as part of first partition programming.

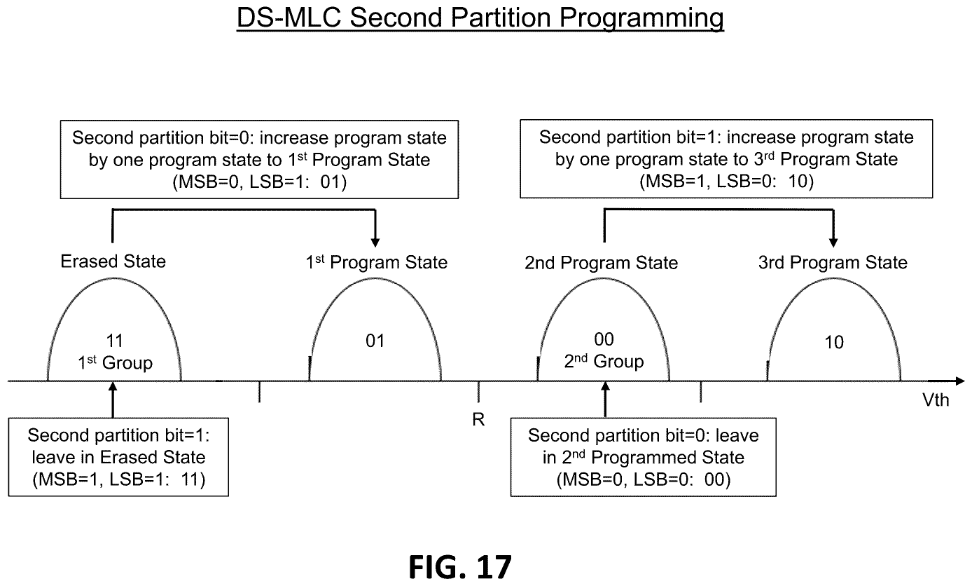

Programming bits (e.g., 0 or 1) from the second partition to the same memory cells involves the MSB's, as illustrated in FIG. 17. Second partition programming begins by identifying the program states for each of the memory cells that resulted from the first partition programming. This can be done using a single level read operation using reference voltage R (to identify memory cells in the erased state with threshold voltages below reference voltage R, and in the second program state with threshold voltages above reference voltage R). The memory cells determined to be in the second program state (referred to as first group) can be operated on first. For each of the first group memory cells, if the bit being programmed from the second partition is 0, the memory cell is left in its current program state (the second program state). If the bit being programmed from the second partition is 1, then the memory cell is programmed to increase its program state by one program state (i.e., programmed to the third program state). After programming the first group memory cells, the memory cells determined to be in the erased program state (referred to as second group) can be operated on next. For each of the second group memory cells, if the bit being programmed from the second partition is 1, the memory cell is left in its current program state (the erased state). If the bit being programmed from the second partition is 0, then the memory cell is programmed to increase its program state by one program state (i.e., programmed to the first program state). Programming of all the second partition bits to memory cells can be performed as set forth above as part of second partition programming. At the end of second partition programming, each memory cell will store one bit of information from the first partition as the LSB, and one bit of information from the second partition as the MSB.

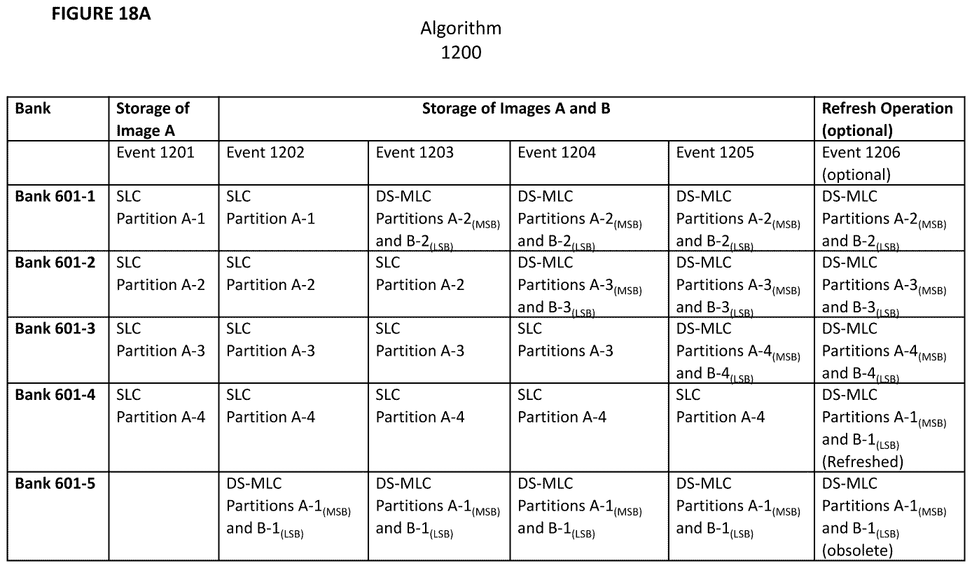

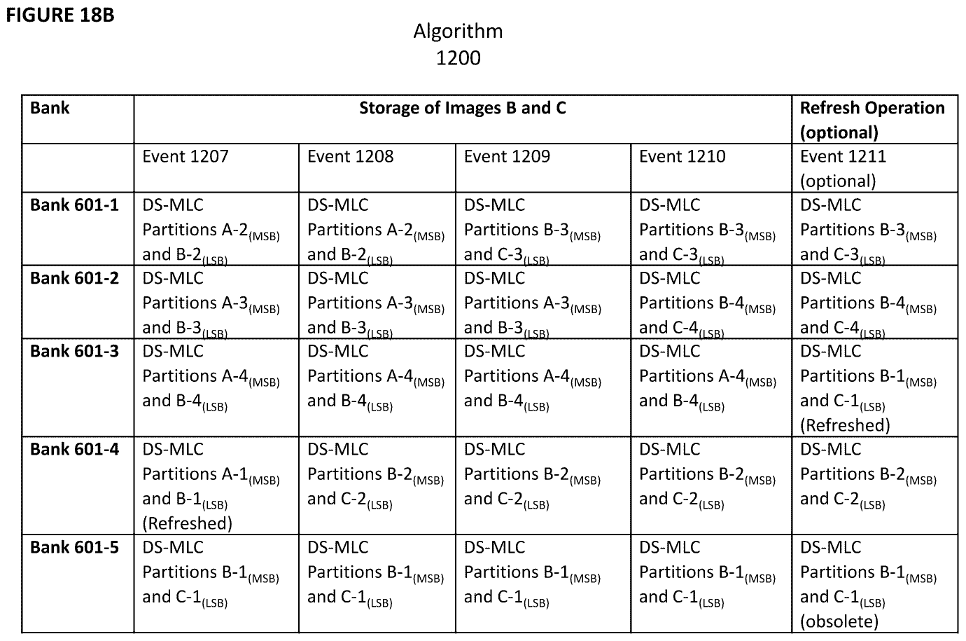

FIGS. 18A and 18B depict algorithm 1200, which comprises an example sequence of events to store images A, B and C in system 100 using DS-MLC format programming, which are examples of image 700 in FIG. 7, in non-volatile storage 600 of FIG. 6. Algorithm 1200 stores images A, B and C in banks 601-1, 601-2, 601-3, 601-4, and 601-5.

Event 1201 is the initial loading of code during the manufacturing process. Image A is stored as partitions A-1, A-2, A-3, and A-4 in banks 601-1, 601-2, 601-3, and 601-4, respectively, using SLC format storage. The benefit of using SLC format instead of MLC format during manufacturing is that the programming process is faster for SLC format than MLC format and using SLC format for event 1201 will decrease manufacturing time. SLC format is also less susceptible to read errors in the event of some charge state drift.

Event 1202 is the beginning of a code update, such as an OTA update, that occurs when system 100 is in the field. Specifically, image B is to be stored, beginning with partition B-1 during event 1202. It is desired to maintain a copy of image A while image B is being stored. Partitions A-1 and B-1 are stored in bank 601-5 using DS-MLC format programming, with Partition A-1 stored in the MSB of the memory cells, and Partition B-1 stored in the LSB of the memory cells. Because banks 601-1, 601-2, 601-3, and 601-4 already contain the entirety of image A, system 100 can store partitions A-1 and B-1 using DS-MLC format programming because there is no time-pressure to complete the operation since image A is available for the system to use. The greater density of DS-MLC format enables bank 605-1 to store both partitions A-1 and B-1 even in the situation where either of those portions would fill nearly the entirety of bank 605-1 when SLC format storage is used.

In event 1203, another portion of image B is similarly stored. Specifically, Partitions A-2 and B-2 are stored in bank 601-1 using DS-MLC format programming.

In event 1204, another portion of image B is similarly stored. Specifically, Partitions A-3 and B-3 are stored in bank 601-2 using DS-MLC format programming.

In event 1205, another portion of image B is similarly stored. Specifically, Partitions A-4 and B-4 are stored in bank 601-3 using DS-MLC format programming. At the conclusion of event 1205, banks 601-1, 601-2, 601-3, and 601-5 collectively contain the entirety of images A and B.

Periodically, system 100 can perform safety read operations to detect possible charge state drift within banks 601-1, 601-2, 601-3, and 601-5 where one or more cells are no longer storing the intended charge state, and determine if a data refresh is needed to correct the drift and prevent system malfunction. This safety read can be performed using a more stringent read condition that that used in code execution (user read), or using an error correction code (ECC) engine during a user read operation. After a certain amount of charge state drift errors have been detected, system 100 can perform a refresh operation whereby data is copied from a first bank, error correction is performed, and the corrected data is stored in a second bank, which will enable code to continue to be executed from the first bank while the refresh operation is performed. In optional event 1206, a refresh operation is performed. In this example, a charge state drift error has been detected in one or both partitions A-1 or B-1. It is to be understood that the charge state drift error can occur and be detected in any partition and that partitions A-1 and B-1 here are used as an example. The system copies the data for partitions A-1 and B-1 from bank 601-5, performs error correction on the data, and stores the refreshed data for partitions A-1 and B-1 in bank 601-4 using DS-MLC format programming.

Event 1207 is the beginning of another code update, such as an OTA update, that occurs when the system is in the field. Specifically, image C is to be stored, beginning with partition C-1 during event 1207. Image A is obsolete because image B is now being executed and image A will be overwritten beginning with event 1207. It is desired to maintain a copy of image B while image C is being stored. Partitions B-1 and C-1 are stored in bank 601-5 using DS-MLC format programming (with partition B-1 in MSB, and partition C-1 in LSB). Because banks 601-1, 601-2, 601-3, and 601-4 already contain the entirety of image B, system 100 can store B-1 and C-1 using DS-MLC format programming because there is no time-pressure to complete the operation since image B is available for the system to use. The greater density of DS-MLC format enables bank 601-5 to store both partitions B-1 and C-1 even in the situation where either of those portions would fill nearly the entirety of bank 605-1 when SLC format storage is used.

In event 1208, another portion of image C is similarly stored. Specifically, Partitions B-2 and C-2 are stored in bank 601-4 using DS-MLC format programming.

In event 1209, another portion of image C DS-is similarly stored. Specifically, Partitions B-3 and C-3 are stored in bank 601-1 using DS-MLC format programming.

In event 1210, another portion of image C is similarly stored. Specifically, Partitions B-4 and C-4 are stored in bank 601-2 using DS-MLC format programming.

In optional event 811, another refresh operation is performed after a charge state drift error is detected in partitions B-1 or C-1. It is to be understood that the charge state drift error can occur and be detected in any partition and that partitions B-1 and C-1 here are used as an example. The system copies the data for partitions B-1 and C-1 from bank 601-5, performs error correction on the data, and stores the refreshed data for partitions B-1 and C-1 in bank 601-3 using DS-MLC format programming.

Additional OTA updates and refresh operations can be performed throughout the lifetime of system 100 using the principles described above for algorithm 1200.

Thus, algorithm 1200 maintains two images beginning when the first code update is complete. It allows for data to be refreshed at any time, as there can always be either one image of factory code, one image of factory code and one image of OTA code, or two images of OTA code that can be used. Algorithm 1200 performs wear leveling within the various banks. All banks experience on average 80% of a DS-MLC erase and program cycle during each code update (as 4 of 5 banks are involved in each code update) and 20% of a DS-MLC erase and program cycle per refresh operation (as 1 of 5 banks are involved in each code update).

DS-MLC format programming is advantageous because it allows for an entire partition to be programmed to the LSB of the memory cells first (in a pseudo SLC format), without involving the second partition to be programmed to the MSB of the memory cells which will happen at a later time (i.e., the first partition is stored, and possibly used, whereby the second partition is programmed later if at all). DS-MLC format programming can reduce system complexity and chip area by removing the need for extra resources for data management. DS-MLC format programming can improve system performance by reducing the number of steps for data manipulation. DS-MLC format programming effectively overlaps a second bit of information over a first bit of information already stored in the memory cell, without any intervening erase operation. During a single read operation on a memory cell, two bits of information from two different partitions are read out simultaneously.

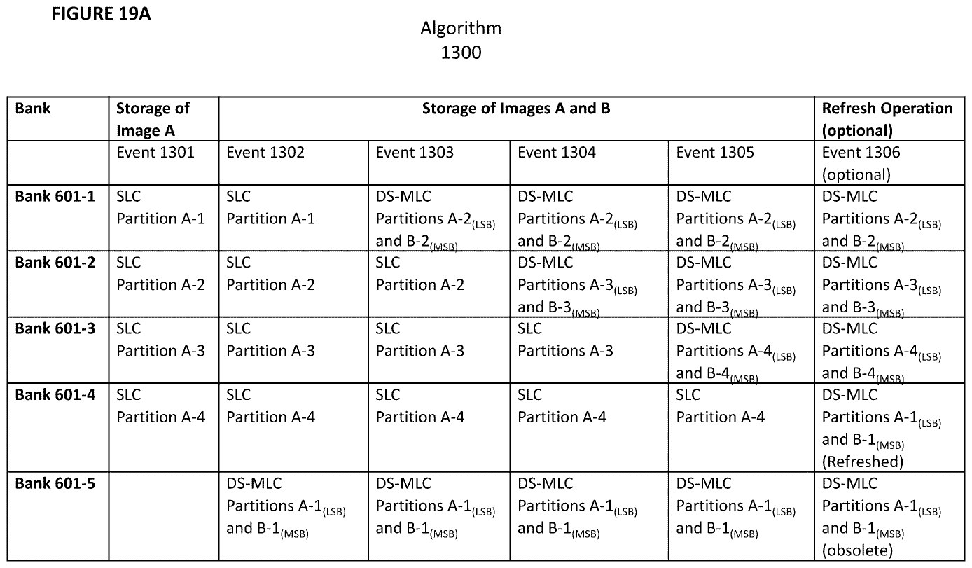

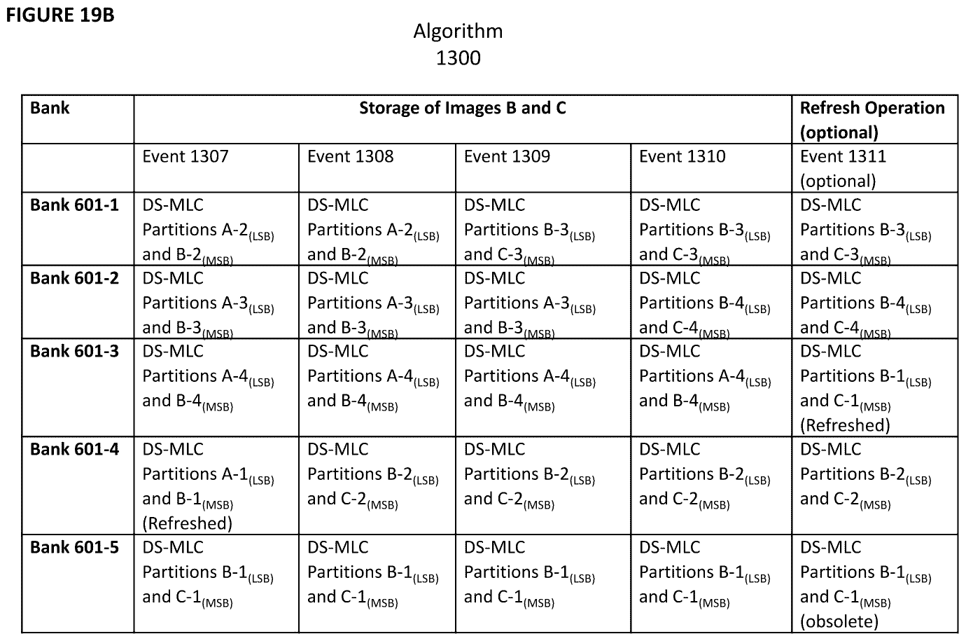

FIGS. 19A and 19B illustrate another example, namely algorithm 1300, which is the same as the algorithm 1200 of FIGS. 18A and 18B, except that during the first OTA update, Partition A is stored as the least significant bits (LSB) instead of the most significant bits (MSB), and Partition B is stored as the most significant bits (MSB) instead of the least significant bits (LSB). Further, during the second OTA update, Partition B is stored as the least significant bits (LSB) instead of the most significant bits (MSB), and Partition C is stored as the most significant bits (MSB) instead of the least significant bits (LSB). In other words, considering the examples of FIGS. 18A, 18B, 19A, 19B together, during any OTA update, the incoming Partition is stored as a first significant bits and the preceding Partition is stored as the second significant bits, where the first significant bits can be either the least significant bits LSB or the most significant bits MSB, and the second significant bits can the other of the least significant bits LSB or the most significant bits MSB.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims.

Materials, processes and numerical examples described above are exemplary only, and should not be deemed to limit the claims. For example, while DS-MLC format is described with respect to four possible program states, additional program states can be used for each memory cell to store more than two bits of information. Further, as is apparent from the claims and specification, not all method operations need be performed in the exact order illustrated or claimed, but rather in any order (unless there is an explicitly recited limitation on any order) that allows the proper operation of the semiconductor device. Single layers of material could be formed as multiple layers of such or similar materials, and vice versa. The terms “forming” and “formed” as used herein shall include material deposition, material growth, or any other technique in providing the material as disclosed or claimed. The claims are comprising claims unless otherwise stated, and therefore “each” of a plurality of elements having a limitation does not preclude the inclusion of additional such elements lacking the limitation unless otherwise specifically claimed. It should be noted that reference herein to circuitry, or a module of circuitry, or the like, to perform or configured to perform an operation refers to the physical structure of the circuit (i.e., the capabilities of the circuitry as dictated by its structure), and does not refer to any method or actual use of the circuitry.

What is claimed is:

1. A method comprising:
storing (n−1) partitions of a first image of code in a first set of banks in single-level cell format, wherein the first set of banks comprise (n−1) of n banks of flash memory cells; and
storing (n−1) partitions of the first image as first significant bits and (n−1) partitions of a second image of code as second significant bits in a second set of banks in dual step multi-level cell format, wherein the second set of banks comprise (n−1) of the n banks and the second set of banks comprises a bank not contained in the first set of banks, and wherein the first significant bits are either least significant bits or most significant bits of the flash memory cells, and the second significant bits are the other of the least significant bits and the most significant bits of the flash memory cells.

2. The method of claim 1, wherein:
the least significant bits are stored in the flash memory cells as first or second program states;
the most significant bits are stored in the flash memory cells as third or fourth program states; and
the third program state is higher than the first program state, the second program state is higher than the third program state, and the fourth program state is higher than the second program state.

3. The method of claim 2, wherein the first program state is an erased state.

4. The method of claim 1, comprising:
receiving the (n−1) partitions of the second image of code over a network interface.

5. The method of claim 1, comprising:
storing (n−1) partitions of the second image as third significant bits and (n−1) partitions of a third image of code as fourth significant bits in a third set of banks in dual step multi-level cell format, wherein the third set of banks comprise (n−1) of the n banks and the third set of banks comprises a bank not contained in the second set of banks, and wherein the third significant bits are either least significant bits or most significant bits, and the fourth significant bits are the other of the least significant bits and the most significant bits relative to the third significant bits.

6. The method of claim 5, comprising:
receiving the (n−1) partitions of the third image of code over a network interface.

7. A method comprising:
storing (n−1) partitions of a first image of code as first significant bits in a first set of banks in dual step multi-level cell format, wherein the first set of banks comprise (n−1) of n banks of flash memory cells; and
storing (n−1) partitions of a second image of code as second significant bits in the first set of banks in dual step multi-level cell format, wherein the first significant bits are either least significant bits or most significant bits of the flash memory cells, and the second significant bits are the other of the least significant bits and the most significant bits of the flash memory cells.

8. The method of claim 7, wherein:
the least significant bits are stored in the flash memory cells as first or second program states;
the most significant bits are stored in the flash memory cells as third or fourth program states; and
the third program state is higher than the first program state, the second program state is higher than the third program state, and the fourth program state is higher than the second program state.

9. The method of claim 8, wherein the first program state is an erased state.

10. The method of claim 7, comprising:
receiving the (n−1) partitions of the second image of code over a network interface.

11. The method of claim 7, comprising:
storing (n−1) partitions of the second image as third significant bits and (n−1) partitions of a third image of code as fourth significant bits in a second set of banks in dual step multi-level cell format, wherein the second set of banks comprise (n−1) of the n banks and the second set of banks comprises a bank not contained in the first set of banks, and wherein the third significant bits are either least significant bits or most significant bits, and the fourth significant bits are the other of the least significant bits and the most significant bits relative to the third significant bits.

12. The method of claim 11, comprising:
receiving the (n−1) partitions of the third image of code over a network interface.

13. A system, comprising:
n banks of flash memory cells; and
circuitry to:
store (n−1) partitions of a first image of code in a first set of banks in single-level cell format, wherein the first set of banks comprise (n−1) of the n banks of flash memory cells; and
store (n−1) partitions of the first image as first significant bits and (n−1) partitions of a second image of code as second significant bits in a second set of banks in dual step multi-level cell format, wherein the second set of banks comprise (n−1) of the n banks and the second set of banks comprises a bank not contained in the first set of banks, and wherein the first significant bits are either least significant bits or most significant bits of the flash memory cells, and the second significant bits are the other of the least significant bits and the most significant bits of the flash memory cells.

14. The system of claim 13, wherein:
the least significant bits are stored in the flash memory cells as first or second program states;
the most significant bits are stored in the flash memory cells as third or fourth program states; and
the third program state is higher than the first program state, the second program state is higher than the third program state, and the fourth program state is higher than the second program state.

15. The system of claim 14, wherein the first program state is an erased state.

16. The system of claim 13, comprising:
a network interface to receive the (n−1) partitions of the second image of code.

17. The system of claim 13, wherein the circuitry to:
store (n−1) partitions of the second image as third significant bits and (n−1) partitions of a third image of code as fourth significant bits in a third set of banks in dual step multi-level cell format, wherein the third set of banks comprise (n−1) of the n banks and the third set of banks comprises a bank not contained in the second set of banks, and wherein the third significant bits are either least significant bits or most significant bits, and the fourth significant bits are the other of the least significant bits and the most significant bits relative to the third significant bits.

18. The system of claim 17, comprising:
a network interface to receive the (n−1) partitions of the third image of code.

19. A system comprising:
n banks of flash memory cells; and
circuitry to:
store (n−1) partitions of a first image of code as first significant bits in a first set of banks in dual step multi-level cell format, wherein the first set of banks comprise (n−1) of the n banks of flash memory cells; and
store (n−1) partitions of a second image of code as second significant bits in the first set of banks in dual step multi-level cell format, wherein the first significant bits are either least significant bits or most significant bits of the flash memory cells, and the second significant bits are the other of the least significant bits and the most significant bits of the flash memory cells.

20. The system of claim 19, wherein:
the least significant bits are stored in the flash memory cells as first or second program states;
the most significant bits are stored in the flash memory cells as third or fourth program states; and
the third program state is higher than the first program state, the second program state is higher than the third program state, and the fourth program state is higher than the second program state.

21. The system of claim 20, wherein the first program state is an erased state.

22. The system of claim 19, comprising:
a network interface to receive the (n−1) partitions of the second image of code.

23. The system of claim 19, wherein the circuitry to:
store (n−1) partitions of the second image as third significant bits and (n−1) partitions of a third image of code as fourth significant bits in a second set of banks in dual step multi-level cell format, wherein the second set of banks comprise (n−1) of the n banks and the second set of banks comprises a bank not contained in the first set of banks, and wherein the third significant bits are either least significant bits or most significant bits, and the fourth significant bits are the other of the least significant bits and the most significant bits relative to the third significant bits.

24. The system of claim 23, comprising:
a network interface to receive the (n−1) partitions of the third image of code.
